(19) United States
(12) Patent Application Publication
(10) Pub. No.: US 2006/0272016 A1
(43) Pub. Date: Nov. 30, 2006

(54) System and method for programming communication devices

(76) Inventors: Elliot M. Stewart, Buffalo Grove, IL (US); Timothy A. Monahan-Mitchell, Mahomet, IL (US)

Correspondence Address: MOTOROLA, INC;INTELLECTUAL PROPERTY SECTION, LAW DEPT, 8000 WEST SUNRISE BLVD, FT LAUDERDAL, FL, 33322, US

(21) Appl. No.: 11/137,193

(22) Filed: May 25, 2005

(51) Int. Cl. G11C 7/00

(52) U.S. Cl. 726/18

(57) ABSTRACT

A system and method for programming a communication device includes various means for programming a plurality of communication devices (115) with a common device management account (120) including a default value for each of one or more device credentials; and deriving a device management account (215) for one of the plurality of communication devices (130) by calculating one or more device management account values for the communication device (130) using a device identification (125) of the communication device (130) and a server identification (255) associated with an assigned device management server (205).

### FIELD OF INVENTION

The present invention relates to communication systems and more particularly to software programming of communication devices.

### BACKGROUND OF THE INVENTION

To facilitate rapid configuration of communication devices, standardized Device Management (DM) tools have been developed to provide service operators the capability to uniquely configure each communication device. Device management is the generic term used for the technology that will allow third parties such as communication service operators to remotely provision and configure communication devices for the end user. This includes remote provisioning of new services, configuration and management of user device parameters and settings, and remote device diagnostics and troubleshooting.

The Open Mobile Alliance (OMA) provides standardized device management operations to allow interoperability among various devices and systems. A large number of device and server manufacturers are currently implementing solutions and participating in the standardization and interoperability work within the OMA.

Initial provisioning of the device, for example, can be accomplished using OMA Client Provisioning technology. With this standardized method, the essential service activation parameters are sent over the air to enable full “out-of-the-box” functionality.

In many communication devices a first phase of programming is performed when the device is manufactured. This typically provides the base features and data that are common to devices of that type. A second round of programming may then be used to provide a set of regional or customer specific requirements, features, security and distribution provisioning. For example, specialized programming may be used to adapt the communication device for use in different communication service networks. This second round of programming is typically accomplished at the communication service provider prior to the device being supplied to the end user.

The OMA DM protocol requires that a relationship (DM account) first be formed between a client device (i.e. a wireless communication device) and a trusted provisioning server (i.e. a DM server) before DM sessions are conducted. The OMA DM specifications detail how this relationship is formed via a bootstrap procedure. The bootstrap procedure can be accomplished via two main mechanisms: (1) Over-the-air (OTA), and (2) Factory provisioning. The OTA bootstrap procedure involves a dedicated server that sends a bootstrap document via some push mechanism, e.g. Wireless Application Protocol (WAP) connectionless push or Object Exchange (OBEX), to the device. The OTA bootstrap process allows for the use of a generic security mechanism whereby a secret that is shared between the device and the server is used in order to authenticate the server. The OMA defines a number of possible shared secrets, some of which require device user input of a pin number. Once the OTA bootstrap document is received by the device and authenticated via the shared secret, the device will provision itself with the contents specified in the bootstrap document. The factory provisioning bootstrap procedure involves loading the non-volatile memory accessible by the device with the bootstrap information at manufacture time. No use of shared secrets is required to provision the bootstrap information with the factory provisioning mechanism.

The difficulty in supporting factory bootstrap provisioning of the DM account is that each device requires unique DM account information (also called credentials) in order to satisfy the security requirements. The unique DM account information creates a burden such that each device must be provisioned with a unique account and that DM account must be communicated back to the DM server, for each device. Additionally, a device may need to be factory bootstrap provisioned to multiple DM servers, each requiring unique DM account information for the credentials.

### BRIEF DESCRIPTION OF THE FIGURES

The accompanying figures, where like reference numerals refer to identical or functionally similar elements throughout the separate views and which together with the detailed description below are incorporated in and form part of the specification, serve to further illustrate various embodiments and to explain various principles and advantages all in accordance with the present invention.

FIG. 1 is an example device programming system in accordance with some embodiments of the invention.

FIG. 2 is an example device management programming system in accordance with some embodiments of the invention.

FIG. 3 is a flowchart illustrating an example of device management programming in accordance with some embodiments of the invention.

FIGS. 4 and 5 are flowcharts illustrating examples of further detail of the device management programming of FIG. 3 in accordance with some embodiments of the invention.

FIG. 6 is an example factory bootstrap DM account profile in accordance with some embodiments of the invention.

FIG. 7 illustrates the DM account profile associated with the DM account of FIG. 6 after the algorithm calculations have been applied in accordance with some embodiments of the invention.

Skilled artisans will appreciate that elements in the figures are illustrated for simplicity and clarity and have not necessarily been drawn to scale. For example, the dimensions of some of the elements in the figures may be exaggerated relative to other elements to help to improve understanding of embodiments of the invention.

### DETAILED DESCRIPTION

Before describing in detail the system and method for programming communication devices in accordance with the present invention, it should be observed that the present invention resides primarily in combinations of method steps and apparatus components related to the system and method for programming communication devices. Accordingly, the apparatus components and method steps have been represented where appropriate by conventional symbols in the drawings, showing only those specific details that are pertinent to understanding the present invention so as not to obscure the disclosure with details that will be readily apparent to those of ordinary skill in the art having the benefit of the description herein.

In this document, relational terms such as first and second, top and bottom, and the like may be used solely to distinguish one entity or action from another entity or action without necessarily requiring or implying any actual such relationship or order between such entities or actions. The terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. An element proceeded by “comprises . . . a” does not, without more constraints, preclude the existence of additional identical elements in the process, method, article, or apparatus that comprises the element.

It will be appreciated the system and method for programming communication devices described herein may be comprised of one or more conventional processors and unique stored program instructions that control the one or more processors to implement, in conjunction with certain non-processor circuits, some, most, or all of the functions of the system and method for programming communication devices described herein. The non-processor circuits may include, but are not limited to, a radio receiver, a radio transmitter, signal drivers, clock circuits, power source circuits, and user input devices. As such, these functions may be interpreted as steps of a method for programming communication devices. Alternatively, some or all functions could be implemented by a state machine that has no stored program instructions, or in one or more application specific integrated circuits (ASICs), in which each function or some combinations of certain of the functions are implemented as custom logic. Of course, a combination of the two approaches could be used. Thus, methods and means for these functions have been described herein. Further, it is expected that one of ordinary skill, notwithstanding possibly significant effort and many design choices motivated by, for example, available time, current technology, and economic considerations, when guided by the concepts and principles disclosed herein will be readily capable of generating such software instructions and programs and ICs with minimal experimentation.

The present invention provides a unique system and method for programming communication devices. The invention as described herein provides, for example, a method for provisioning unique OMA DM accounts into individual OMA DM capable devices through a factory bootstrap of a common account. The means employed also allows for the unique factory bootstrap provisioning of multiple DM accounts by incorporating both the device ID (for example: International Mobile Equipment Identity (IMEI) for Global System for Mobile Communications Systems (GSM) and Universal Mobile Telecommunications Systems (UMTS) or electronic serial number (ESN) or Mobile Equipment Identification (MEID) for Code Division Multiple Access Systems (CDMA)) and the DM Server ID (which is unique across DM servers in the device). It will be appreciated by those of ordinary skill in the art that the present invention can be implemented using any combination of the device IDs and server IDs within any communication system mentioned herein or an equivalent.

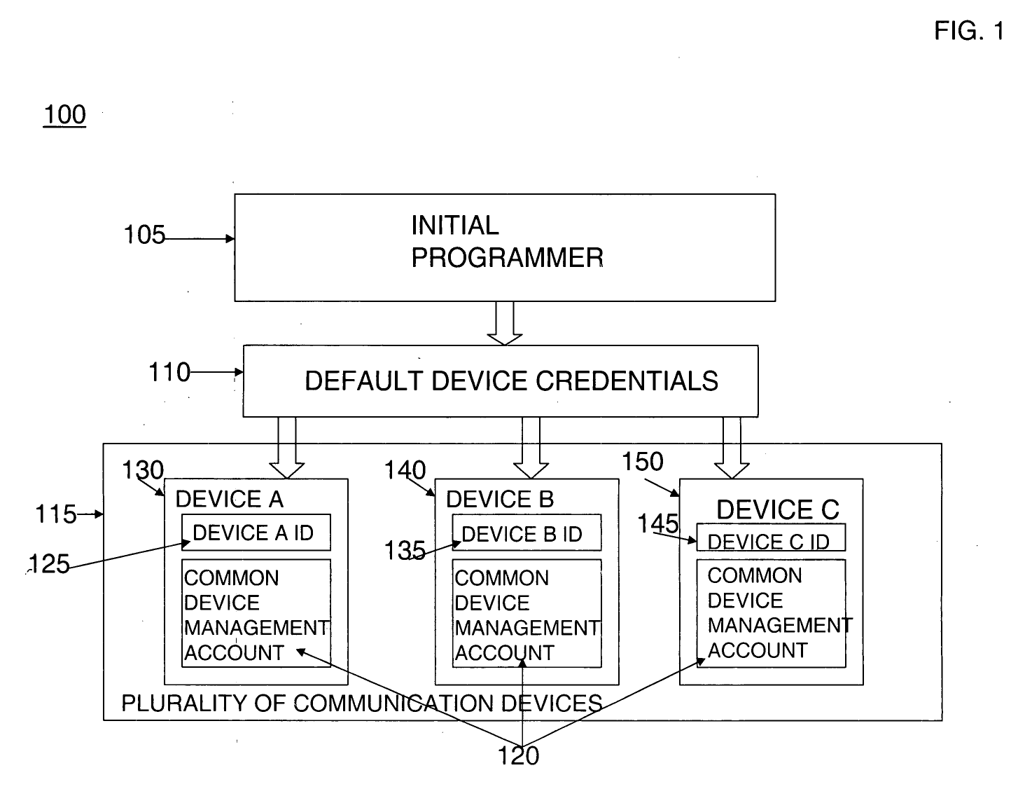

Referring to FIG. 1, an exemplary device programming system 100 in accordance with some embodiments of the invention is illustrated. The device programming system 100, for example, can be a device programming system located within a device manufacturing facility. The device programming system 100 preferably includes an initial programmer 105 coupled to a plurality of communication devices 115.

It will be appreciated by one of ordinary skill in the art that each of the plurality of communication devices 115, in accordance with the present invention, can be a mobile cellular telephone, a mobile radio data terminal, a mobile cellular telephone having an attached or integrated data terminal, a two-way messaging device, or an equivalent. Similarly, the communication device can be any other electronic device such as a personal digital assistant or a laptop computer having wireless communication capabilities. In the following description, the term “communication device” refers to any combination of the devices mentioned above or an equivalent.

It will further be appreciated by one of ordinary skill in the art that each of the communication devices, in accordance with the present invention, can operate within networks utilizing at least one of several standards. These standards include analog, digital or dual-mode communication system protocols such as, but not limited to, the Advanced Mobile Phone System (AMPS), the Narrowband Advanced Mobile Phone System (NAMPS), the Global System for Mobile Communications (GSM), the IS-136 Time Division Multiple Access (TDMA) digital cellular system, the IS-95 Code Division Multiple Access (CDMA) digital cellular system, the CDMA 2000 system, the Wideband CDMA (W-CDMA) system, the Personal Communications System (PCS), the Third Generation (3G) system, the Universal Mobile Telecommunications System (UMTS) and variations and evolutions of these protocols. In the following description, the term “communication system” refers to any of the systems mentioned above or an equivalent. Additionally, it is envisioned that communication systems can include wireless local area networks, including pico-networks, or the like.

The initial programmer 105 programs a unique device identification (ID) into each of the plurality of communication devices 115. For example, Device A (130) is programmed with device A ID (125), Device B (140) is programmed with device B ID (135), and device C (150) is programmed with device C ID (145) as illustrated in FIG. 1. The device identification, for example, can be a unique selective call address assigned within a wireless communication system, an electronic mail address, an IP (internet protocol) address an IMEI, an ESN, or any other similar identification.

The initial programmer 105, in accordance with the present invention, pre-provisions each of the plurality of communication devices 115 with configuration data. Preferably, the configuration data includes a common device management account 120 that is the same for all devices being programmed. For example, the initial programmer 105, provides one or more default device credentials 110 to each of the plurality of communication devices 115. The default device credentials 110 can be special reserved values which are programmed into one or more of the client user name, the client password, and the server password DM account nodes. In summary, the initial programmer 105 programs all of the plurality of communication devices 115 with the same DM account values thus removing traditional factory steps to prepare, program, track and communicate unique data for each individual communication device.

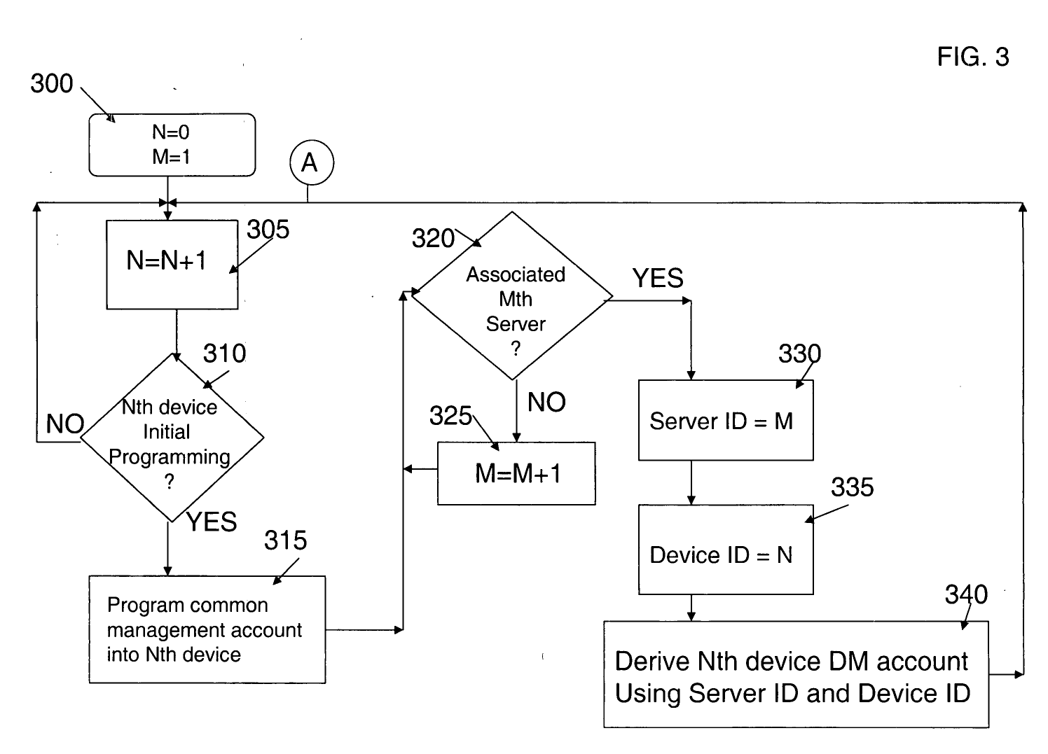

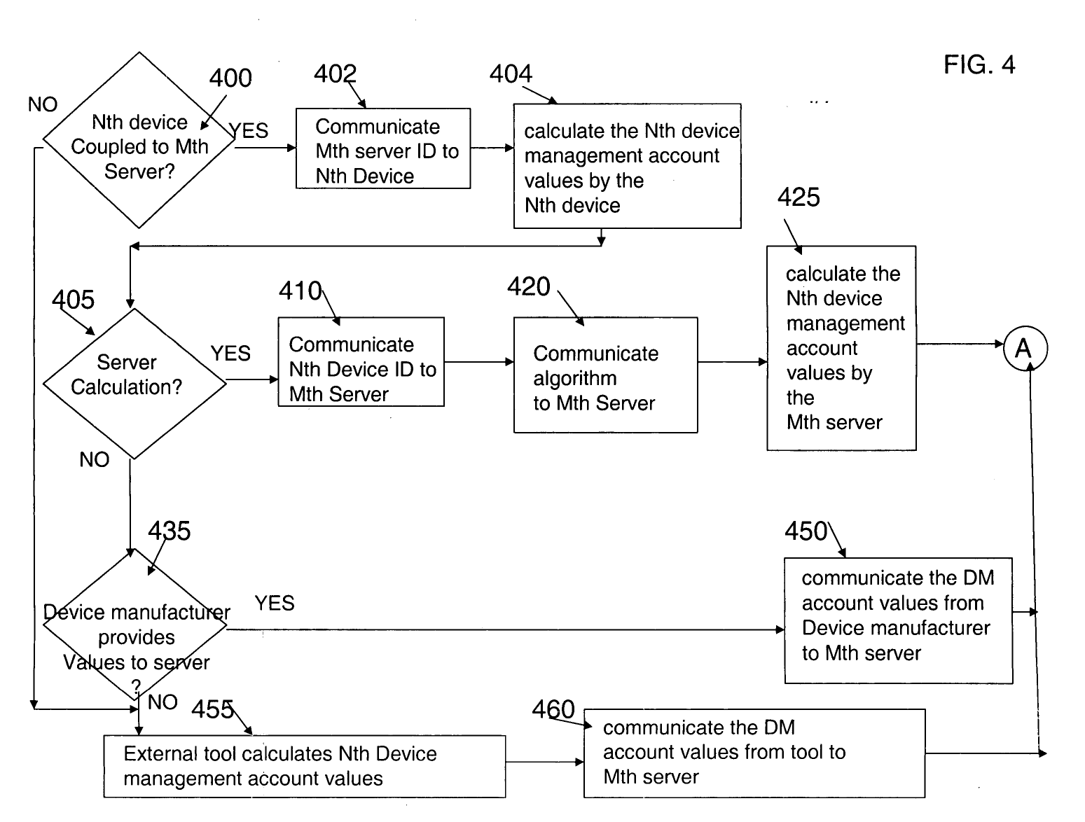

In one embodiment, each of the plurality of communication devices 115 are programmed by the initial programmer 105 with an algorithm for deriving new values for the DM account nodes at a later time to create a unique device management account. The algorithm preferably uses the device ID and an associated server ID to calculate the unique values as will be described in detailed in association with FIGS. 3 and 4 herein.

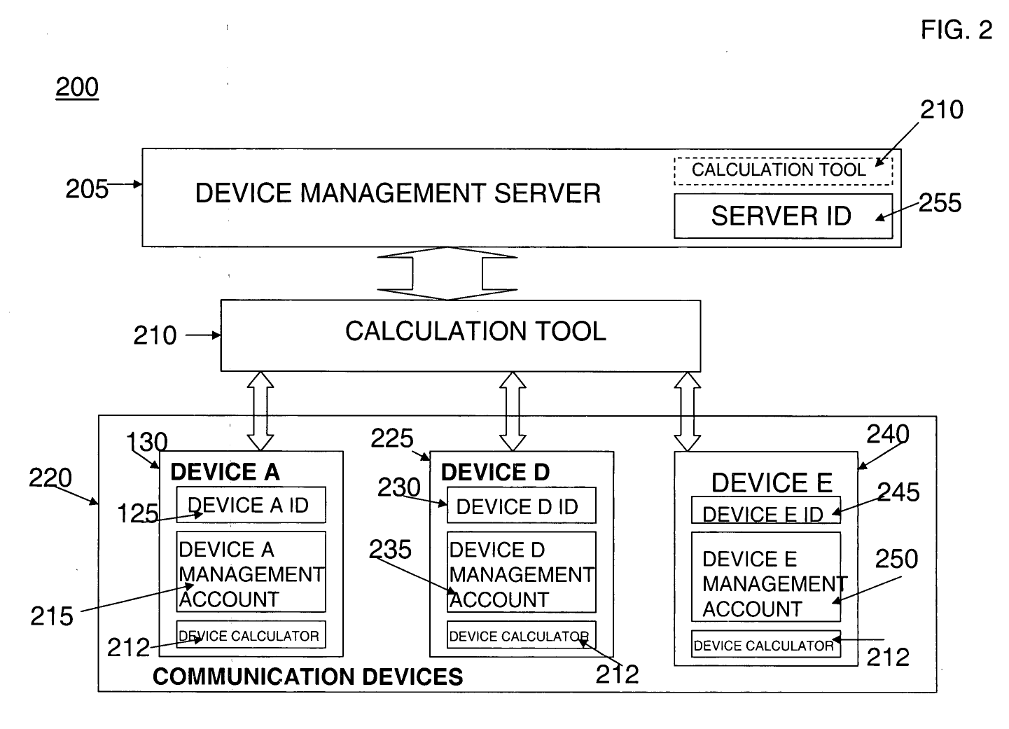

Referring to FIG. 2, an exemplary device management programming system 200 in accordance with some embodiments of the invention is illustrated. The device management programming system 200 includes a device management server 205 and one or more associated communication devices 220. The device management server 205 provides a second round of programming to the associated communication devices 220 including, for example, a set of regional or customer specific requirements, features, security and distribution provisioning For example, the device management server 205 can program each of the associated communication devices 220 for use in the associated carrier networks. The device management programming system 200, is typically located at the service operator for programming prior to the communication device being provided to the end user. Alternatively, the device management programming system 200 can be co-located with retail locations and the like where the end user obtains the communication device.

The device management server 205 is programmed with a unique server identification (ID) 255. The server identification, for example, can be a unique selective call address assigned within a wireless communication system, an electronic mail address, an IP (internet protocol) address or any other similar identification.

Each of the plurality of communication devices 220 within the device management programming system 200 includes a device calculator 212 for deriving a device management account for each of the associated communication devices 220 by calculating one or more device management account values for the communication device using a device identification of the communication device and the server identification 255 associated with the device management server 205. For example, the device calculator 212 within the device A 130 can derive a device A management account 215 for device A 130 using the device A ID 125 and the server ID 255. Similarly, the device calculator 212 within the device D 225 can derive a device D management account 235 for device D 225 using the device D ID 230 and the server ID 255. Similarly, the device calculator 212 within the device E 240 can derive a device E management account 250 for device E 240 using a device E ID 245 and the server ID 255. It will be appreciated by those of ordinary skill in the art that the server ID 255 can be provided to the device calculator 212 of each of the plurality of communication devices 220 by the device management server 205, can be programmed directly at the factory or another secondary location, can be entered via a user input to each device, or any equivalent method.

In accordance with the present invention, a calculation tool 210 within the device management programming system 200 has a similar capability to the device calculator 212. For example, the calculation tool 210 can derive a device A management account 215 for device A 130 using the device A ID 125 and the server ID 255. Similarly, the calculation tool 210 can derive a device D management account 235 for device D 225 using the device D ID 230 and the server ID 255. Similarly, the calculation tool 210 can derive a device E management account 250 for device E 240 using a device E ID 245 and the server ID 255. In accordance with the present invention, the calculation tool 210 can be contained within the device management server 205, communicated from the device manufacturer, and/or an external calculation tool.

For example, the device management server 205 could have a calculation algorithm coded into it, so as to automatically pre-provision new device accounts internally. For example, the device manufacturer can provide to the DM server manufacturer the algorithms to add to its code. When new accounts are entered into the DM server, which contain the reserved values for certain parameters the result is the DM server calculates the same unique DM account profile as will be present in the client at the start. For example, the parameters of DMAcc/x/ServerPW, (node which holds the password or secret that the server will use to authenticate itself to the client), DMAcc/x/UserName, (node which stores the name of the user (or device) for use in DM authentication), and DMAcc/x/ClientPW (node which holds the password or secret that the client will use to authenticate itself to the server) can contain reserved values. In order for the DM server to create an account, the device ID, and the like can be provided. Typically, the device management server 205 has stored (i.e. has knowledge of) its own server ID (255).

Alternatively, the device management server 205 can receive the computed account information directly from the device manufacturer, which would alleviate the device management server 205 from knowing how to derive the account information.

Alternatively, the calculation tool 210 can be provided to the communication service operator/device management server which implements the algorithm; a list of unique device IDs and the server ID to which the devices are to be bootstrapped is input with the output showing the unique DM account information per device. For example, the device manufacturer can create a program that knows how to generate UserName, ClientPW, and ServerPW values based on the necessary inputs of the algorithms. The program is delivered to the carrier or DM server manufacturer as a tool to assist in populating the DM account nodes whose values are generated. The implementation of the program preferably considers portability and environment issues, such as the operating system and hardware platform where it needs to be run. In order for the user of the program to create an account, the device ID can be provided.

In an alternate implementation, both the initial programming and the secondary programming can be accomplished at the device manufacturer. In this approach, the device manufacturer provides to the DM server the complete set of DM account node values for each device. The device manufacturer will have knowledge already of all the node settings, through the process of creating the default DM account factory bootstrap flex file as well as possessing the algorithms used to calculate unique values from the default DM account. The DM account information for the list of client devices can be presented in a spreadsheet or a CSV file (“Comma Separated Values” which is a file format for storing a group of data values that is easily parsed into separate data values for further processing. Text values are separated by commas. A CSV file can be easily imported into a spreadsheet).

In practice, unique DM account information can be derived for each communication device at first power up. The initially programmed reserved account values trigger the calculation tool to calculate unique DM account values using a pre-defined algorithm. The calculated values then replace the reserved account values. For example, Device A 130 is initially programmed with the common device management account 120. Upon power up at the carrier's operation, device A 130 associates with the device management server 205 and the calculation tool 210 using a pre-programmed algorithm, the device A ID 125, and the server ID 255 to calculate the device A management account 215. The device A management account 215 then replaces the common device management account 120 (FIG.1)within device A 130.

There are numerous benefits to the system described herein. For example, use of both unique device information and unique server information allows multiple unique DM accounts to be created, allowing one phone to be managed by multiple DM servers. Further, the use of algorithms for DM account generation solves the problem of out-of-band communication of device account information to the server for the factory bootstrap method. Further, the DM client receives its DM account for a corresponding DM server at the factory and is shipped with the account present as opposed to having to retrieve wirelessly (i.e. over the air (OTA)) after in the hands of a consumer.

FIG. 3 is a flowchart illustrating an example of device management programming in accordance with some embodiments of the invention. As illustrated, the process begins with Step 300 in which two parameters N and M are each initialized such that N=0 and M=1. Next, in Step 305, the parameter N is incremented to N=N+1. Next, in Step 310, the operation determines whether an Nth device requires initial programming. When there is not an Nth device that requires initial programming, the operation cycles back to Step 305 and N is incremented to N=N+1. When there is an Nth device that requires initial programming in Step 310, the operation continues to Step 315 in which a common device management account is programmed into the Nth device. Next, in Step 320, the operation determines whether an Mth server has been associated with the Nth device. When the Nth device is not associated with the Mth server, the operation continues to Step 325 in which the M parameter is incremented to M=M+1. The operation then returns to Step 320 to check for association of the Nth device with the Mth server.

When, in Step 320, the Nth device is associated with the Mth server, the operation continues to Step 330 in which the server ID is set to M. Next, in Step 335 the device ID is set to N. Next in Step 340 the Nth device DM account is derived using the Server ID and the Device ID. The operation then returns to Step 305 in which the N parameter is incremented to N=N+1. (node A)

FIG. 4 is a flowchart illustrating further detail of the device management programming of FIG. 3 in accordance with some embodiments of the invention. Specifically, FIG. 4 illustrates further detail of the derivation Step 340 of FIG. 3. As illustrated, the operation begins with Step 400 in which the operation determines whether or not the Nth device is coupled (i.e. electrically, mechanically, and/or communicatively connected) to the Mth server. Please note that in an alternative embodiment (not shown) Step 400 can be optional and the process can begin with Step 402. Returning to the flowchart as illustrated in FIG. 4, when the Nth device is coupled to the Mth server, the operation continues to Step 402 in which the Mth server ID is communicated to the Nth device.

Next, in Step 404, the Nth device calculates the Nth device management account values by using the calculation algorithm (which is pre-programmed into the Nth device) operating on the Nth device ID and the Mth server ID. Next, in Step 405, the operation determines whether or not a DM server calculation is to be implemented. When a DM server calculation is to be implemented in Step 405, the operation continues to Step 410 in which the Nth device ID is communicated to the Mth server. It will be appreciated by those of ordinary skill in the art that the Nth device ID can be communicated by the Nth device itself, by the device manufacturer, or pre-programmed into the DM server by the communication service provider, or in an equivalent manner. The operation continues to Step 420 in which the calculation algorithm is communicated to the Mth server. It will be appreciated by those of ordinary skill in the art that the Mth server will either be given the algorithm by the device manufacturer so that the server vendor implements the algorithm into the Mth server, the Mth server can be given a tool that embodies the algorithm with the tool used by the service provider to generate the same account found in the device to input into the server, or the Mth server will be given the DM account values by the device manufacturer for each device in e.g., a CSV file. Next, the operation proceeds to Step 425 in which the Mth server calculates the Nth device management account values by using the calculation algorithm operating on the Nth device ID and the Mth server ID. The operation then returns to node A of FIG. 3.

Returning to Step 405, when a server calculation is not to be implemented, the operation proceeds to Step 435 in which it is determined whether the device manufacturer is to provide the calculation to the server. When the device calculation is to be provided to the server by the device manufacturer in Step 435, the operation continues to Step 450, in which the device manufacturer provides the Nth device DM account values to the Mth server. The operation then returns to node A of FIG. 3.

Returning to Step 435, when the device manufacturer is not providing the calculation to the server, and when the Nth device is not coupled to the Mth server in Step 400, the operation continues to Step 455 in which an external calculation tool is used to derive the Nth device management account values by using the calculation algorithm (which can be pre-programmed into the calculation tool) operating on the Nth device ID and the Mth server ID. Next, in Step 460, the calculation tool communicates the DM account values to the Nth device and the Mth server. The operation then returns to node A of FIG. 3.

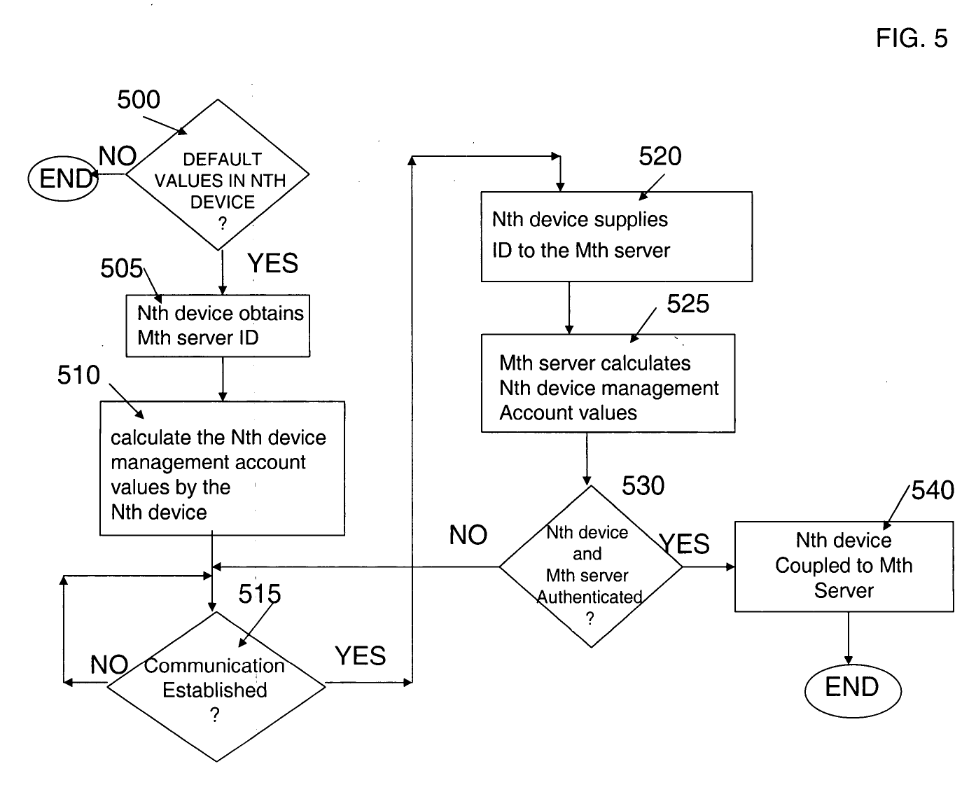

FIG. 5 is a flowchart illustrating further detail of the device management programming of FIG. 3 in accordance with some embodiments of the invention. Specifically, FIG. 5 illustrates further detail of the derivation Step 340 of FIG. 3. As illustrated, the operation begins with Step 500 in which it is determined whether or not the DM account values within the communication device are set to default values. When default values are present, the operation continues to Step 505 in which the Nth device obtains the Mth server ID. It will be appreciated by those of ordinary skill in the art that the Nth device can obtain the Mth server ID by having it programmed at the device manufacturer, by being entered manually through a user input into the Nth device, by communicating a request for the Mth server ID and in response receiving the Mth server ID from the communication service provider, or any equivalent method. Next, in Step 510, the Nth device calculates the Nth device management account values by using the calculation algorithm (which is pre-programmed into the Nth device) operating on the Nth device ID and the Mth server ID. Next, in Step 515, the Nth device attempts to establish communication with the Mth DM server. When communication is not established, the Nth device periodically attempts to establish communication. When communication is established in Step 520, the Nth device supplies the Nth device ID to the Mth server. Next, in Step 525, the Mth server performs the calculation using the Nth device ID and Mth server ID using a calculation tool embedded in the server. After Step 525, the operation continues with Step 530 in which it is determined whether the Nth device and the Mth server are authenticated. When the Nth device and Mth server are authenticated in Step 530, the operation continues to Step 540 in which the Nth device and Mth server are coupled. Next, the operation ends. When the Nth device and Mth server are not authenticated in Step 530, the operation returns to Step 515 waiting for device N to establish contact with the Mth server again.

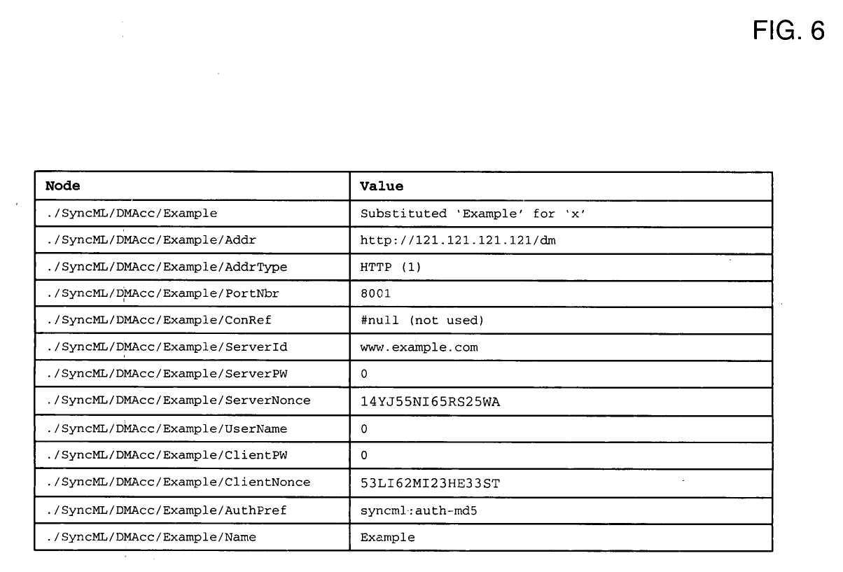

FIG. 6 is an example factory bootstrap DM account profile. Certain nodes (for example: ServerPW, ClientPW, and Username) contain special reserved values (for example: the values can be zero) that trigger the entity responsible for DM account profile processing to calculate unique values based on the algorithms defined in this paper. For this example, the device is GSM technology with the IMEI equal to 001010123456789.

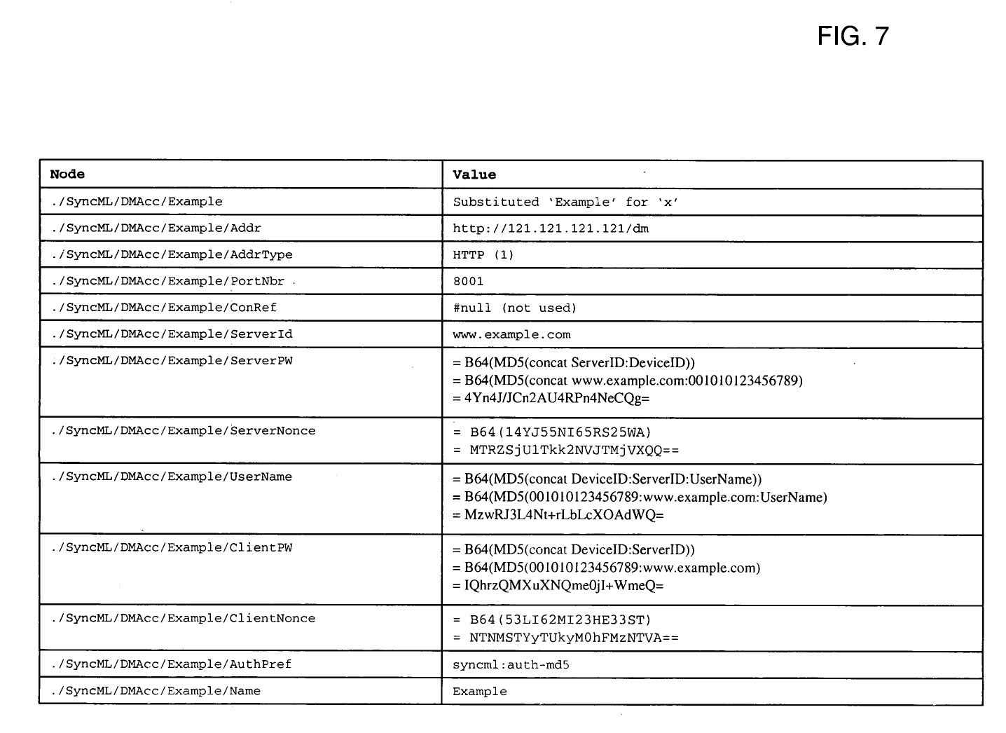

FIG. 7 illustrates the DM account profile associated with the DM account of FIG. 6 with the algorithm calculations done on the ServerPW, ClientPW, and UserName nodes. In the illustrated algorithm, MD5 is a secure hash algorithm, and B64 is a means to convert arbitrary binary data into a subset of ASCII printable characters suitable for many types of transmission as will be appreciated by those of ordinary skill in the art. Please note that the algorithm of FIG. 7 is for exemplary purposes only. Any equivalent algorithm which yields unique values, given unique input values, is within the scope of the present invention.

In the foregoing specification, the invention and its benefits and advantages have been described with reference to specific embodiments. However, one of ordinary skill in the art appreciates that various modifications and changes can be made without departing from the scope of the present invention as set forth in the claims below. Accordingly, the specification and figures are to be regarded in an illustrative rather than a restrictive sense, and all such modifications are intended to be included within the scope of present invention. The benefits, advantages, solutions to problems, and any element(s) that may cause any benefit, advantage, or solution to occur or become more pronounced are not to be construed as a critical, required, or essential features or elements of any or all the claims. The invention is defined solely by the appended claims including any amendments made during the pendency of this application and all equivalents of those claims as issued.

What is claimed is:

1. A method for programming a communication device comprising the steps of:
programming a plurality of communication devices with a common device management account including a default value for each of one or more device credentials; and
deriving a device management account for one of the plurality of communication devices by calculating one or more device management account values for the communication device using a device identification of the communication device and a server identification associated with an assigned device management server.

2. A method as recited in claim 1, wherein the one or more device credentials is selected from a group comprising a client user name, a client password, and a server password.

3. A method as recited in claim 1, wherein the deriving step comprises:
communicating the device identification to the device management server; and
calculating the device management account values by the device management server.

4. A method as recited in claim 3, further comprising:
coupling the communication device to the device management server prior to the communicating step.

5. A method as recited in claim 3, wherein the device identification is communicated to the device management server by one of the group comprising the communication device, the device manufacturer, and the communication service provider.

6. A method as recited in claim 3, further comprising, prior to the coupling step, the step of:
providing an algorithm associated with the device identification to the device management server,
wherein the calculating step uses the algorithm to calculate the device management account values.

7. A method as recited in claim 1, wherein the deriving step comprises:
communicating the server identification to the communication device;
calculating the device management account values by the communication device; and
communicating the device management account values from the communication device to the device management server.

8. A method for programming a plurality of communication devices including a first communication device and a second communication device, the method comprising the steps of:
programming the plurality of communication devices with a common device management account including a default value for each of one or more device credentials;
deriving a first device management account for a first communication device by calculating a first set of device management account values for the first communication device using a first device identification of the first communication device and a server identification associated with an assigned device management server; and
deriving a second device management account for the second communication device by calculating a second set of device management account values for the second communication device using a second device identification of the second communication device and the server identification associated with an assigned device management server.

9. A method as recited in claim 8, wherein the one or more device credentials is selected from a group comprising a client user name, a client password, and a server password.

10. A method as recited in claim 8, wherein the deriving step comprises:
communicating the first device identification to the device management server;
calculating the first set of device management account values by the device management server;
communicating the second device identification to the device management server; and
calculating the second set of device management account values by the device management server.

11. A method as recited in claim 10, further comprising, prior to the coupling step, the step of:
providing an algorithm associated with the first device identification and the second device identification to the device management server,
wherein the calculating steps use the algorithm to calculate the first set of device management account values and the second set of device management account values.

12. A method as recited in claim 8, wherein the deriving step comprises:
communicating the server identification to the first communication device;
calculating the first set of device management account values by the first communication device;
communicating the first set of device management account values from the first communication device to the device management server;
communicating the server identification to the second communication device;
calculating the second set of device management account values by the second communication device; and
communicating the second set of device management account values from the second communication device to the device management server.

13. A system for programming a plurality of communication devices comprising:
the plurality of communication devices;
a programmer for programming the plurality of communication devices with a common device management account including a default value for each of one or more device credentials;
a device management server communicatively coupled to a communication device; and
a calculation tool for deriving a device management account for the communication device, the calculation tool including a processor for calculating one or more device management account values for the communication device using a device identification of the communication device and a server identification of the device management server.

14. A system as recited in claim 13, wherein the one or more device credentials is selected from a group comprising a client user name, a client password, and a server password.

15. A system as recited in claim 13, wherein the calculation tool is coupled to the device management server.

16. A system as recited in claim 13, wherein the calculation tool is contained within the device management server.

17. A system as recited in claim 13, wherein the calculation tool is contained within the communication device.

18. A system as recited in claim 13, wherein the one or more communication devices includes a second communication device having a second device identification, and
further wherein the calculation tool is adapted to derive a second device management account for the second communication device, the calculation tool including a processor for calculating a second set of device management account values for the second communication device using the second device identification of the second communication device and a server identification of the device management server.
